(19) United States
(12) Patent Application Publication
(10) Pub. No.: US 2024/0162161 A1
(43) Pub. Date: May 16, 2024

(54) METHOD FOR PREPARING DIELECTRIC LAYER ON SURFACE OF WAFER, WAFER STRUCTURE, AND METHOD FOR SHAPING BUMP

(71) Applicants: CHIPMORE TECHNOLOGY CORPORATION LIMITED, Suzhou, Jiangsu (CN); HEFEI CHIPMORE TECHNOLOGY CO., LTD., Heifei, Anhui (CN)

(72) Inventor: Guanmeng XU, Suzhou (CN)

(73) Assignees: CHIPMORE TECHNOLOGY CORPORATION LIMITED, Suzhou, Jiangsu (CN); HEFEI CHIPMORE TECHNOLOGY CO., LTD., Heifei, Anhui (CN)

(21) Appl. No.: 18/280,918

(22) PCT Filed: Nov. 23, 2021
(86) PCT No.: PCT/CN2021/132274

§ 371 Date: Sep. 7, 2023

(30) Foreign Application Priority Data
Jun. 30, 2021 (CN) 202110735094.7

(51) Int. Cl. H01L 23/544; H01L 21/02; H01L 23/00

(52) U.S. Cl. CPC H01L 23/544; H01L 21/02307; H01L 24/04; H01L 24/11; H01L 2223/54426; H01L 2224/0401; H01L 2224/05013; H01L 2224/05083; H01L 2224/05147; H01L 2224/05171; H01L 2224/11618

(57) ABSTRACT

The present invention provides a method for preparing a dielectric layer on a surface of a wafer, a wafer structure, and a method for shaping a bump. The preparation method includes: providing a wafer; forming an alignment mark on the wafer, the thickness of the alignment mark being not less than 0.3 μm; and forming a dielectric layer on the wafer where the alignment mark is formed. In the present application, before the dielectric layer is shaped on a surface of the wafer, the alignment mark is prepared in advance on the surface of the wafer, thereby avoiding the need of reworking due to an invisible alignment mark in a preparation stage of the dielectric layer, and ensuring the continuity of the process.

### TECHNICAL FIELD

The present invention relates to the field of semiconductor packaging technologies, in particular to a method for preparing a dielectric layer on a surface of a wafer, a wafer structure, and a method for shaping a bump.

### BACKGROUND ART

In a manufacturing process of a semiconductor device, almost every step of a photolithography technique relates to an alignment or aligning process. The so-called alignment or aligning process refers to recognition of a special alignment mark on a substrate surface by a machine on photolithographic equipment or by human eyes, so that there is an overlap in position between a latter technique and a former technique. For a wafer, misplacement caused by inaccurate alignment can result in distortion of a subsequent pattern or misalignment of registration, which ultimately affects an electrical characteristic of the semiconductor device in an adverse manner.

In the field of wafer packaging testing, since a surface of a wafer is usually distributed with a large number of IC circuit layers, a wafer packaging testing technique becomes particularly critical. At present, a height difference of IC circuit layers on surfaces of some wafers is too small, only about 0.1 μm; when a dielectric layer is processed in a packaging stage (such as PI covering), a circuit layer at the bottom cannot be displayed after the surface of the wafer is coated with a photoresist; and as a result, an alignment mark on the surface of the wafer is completely invisible after being covered with the photoresist, leading to failure of an exposure machine to subsequently recognize the alignment mark, and disabling continuous production. In this case, a packaging manufacturer has to return the wafer to an upstream wafer provider to re-make the alignment mark. Obviously, this will be very cumbersome, and thus, a packaging manufacturer cannot carry out continuous production, greatly reducing the production efficiency. It can be seen that how to enable the alignment mark on the surface of the wafer to be still visible after the dielectric layer is formed is a technical problem that needs to be solved.

### SUMMARY OF THE INVENTION

A technical problem solved by the present application is to provide a method for preparing a dielectric layer on a surface of a wafer, so as to improve the problem of an unclear alignment mark in the prior art.

In order to solve the above technical problem, the present application provides a method for preparing a dielectric layer on a surface of a wafer, including:
providing a wafer, wherein the wafer is provided with a substrate, a bonding pad formed on the substrate and a passivation layer, and the bonding pad is exposed outwardly from a passivation layer opening in the passivation layer;
covering an upper surface of the wafer with a metal layer having a thickness of not less than 0.3 μm, wherein the metal layer is a UBM layer shaped on the upper surface of the wafer;
covering an upper surface of the metal layer with a photoresist to form a photoresist layer;
removing the photoresist layer other than a target position, such that the remaining photoresist layer forms a photoresist block above the target position, and the metal layer other than the target position is exposed outwardly;
removing the photoresist block after the outwardly exposed metal layer other than the target position is removed, so as to enable the metal layer at the target position to form a metal block which is used as an alignment mark on the upper surface of the wafer and is only arranged on the passivation layer; and
forming a dielectric layer on the upper surface of the wafer where the metal block is formed.

Further, the UBM layer includes a chromium layer, a chromium-copper layer and a copper layer from bottom to top.

Further, the “removing the photoresist layer other than a target position” includes:
shielding a photoresist layer at the target position by using a mask, and exposing the photoresist layer other than the target position; and
removing the photoresist other than the target position by means of a development technique.

Further, the development technique is to dissolve the photoresist in a region other than the target position by using a chemical developer, so as to enable the metal layer under the photoresist to be exposed on the surface of the wafer.

A wafer structure includes: a substrate, a bonding pad formed on the substrate and a passivation layer, wherein the bonding pad is exposed outwardly from a passivation layer opening in the passivation layer; and
an alignment mark is formed on an upper surface of the passivation layer, and is a metal block with a thickness of not less than 0.3 μm.

Further, the metal block is a UBM layer.

A method for shaping a bump includes:
providing a wafer, wherein the wafer is provided with a substrate, a bonding pad formed on the substrate and a passivation layer, and the bonding pad is exposed outwardly from a passivation layer opening in the passivation layer;
covering an upper surface of the wafer with a metal layer having a thickness of not less than 0.3 μm, wherein the metal layer is a UBM layer shaped on the upper surface of the wafer;
covering an upper surface of the metal layer with a photoresist to form a photoresist layer;
removing the photoresist layer other than a target position, such that the remaining photoresist layer forms a photoresist block above the target position, and the metal layer other than the target position is exposed outwardly;
removing the photoresist block after the outwardly exposed metal layer other than the target position is removed, so as to enable the metal layer at the target position to form a metal block which is used as an alignment mark on the upper surface of the wafer and is only arranged on the passivation layer; forming a dielectric layer on the upper surface of the wafer where the alignment mark is formed;
removing the dielectric layer above the passivation layer opening to outwardly expose the bonding pad;
covering an upper surface of the dielectric layer and an upper surface of the bonding pad with a seed layer;
forming a photoresist layer on the seed layer, and then removing the photoresist layer at the target position to form a photoresist layer pane for outwardly exposing the bonding pad; and
shaping a metal bump in the photoresist layer pane.

Compared with the prior art, the present application optimizes the preparation technique of the dielectric layer of the wafer, in which the alignment mark is prepared in advance on the surface of the wafer before the dielectric layer is shaped on the surface of the wafer. Since the thickness of the alignment mark is 0.3 μm or more, the alignment mark is relatively prominent and easily visible, and can be effectively recognized and used for positioning in a subsequent technique of the wafer (such as a preparation stage of the dielectric layer), which is beneficial to the proceeding of the subsequent technique, effectively avoids the problem of reworking due to the invisible alignment mark in the preparation stage of the dielectric layer, ensures the continuity of the process technique, improves the production efficiency and also saves the labor and material costs of the reworking.

### BRIEF DESCRIPTION OF THE DRAWINGS

FIG. 1 is a flow chart of a method for preparing a dielectric layer on a surface of a wafer according to the present application;

FIGS. 2-8 are schematic technique diagrams of a process for shaping an alignment mark in the dielectric layer on the surface of the wafer according to the present application; and

FIG. 9 is a schematic structural diagram of the alignment mark in the wafer according to the present application.

Reference numerals: 10—wafer, 101—bonding pad, 20—alignment mark, 30—metal layer, 40—photoresist layer, and 401—photoresist block.

### DETAILED DESCRIPTION

Embodiments described below in combination with the accompanying drawings are exemplary and are only used to explain the present invention, and should not be construed as limiting the present invention.

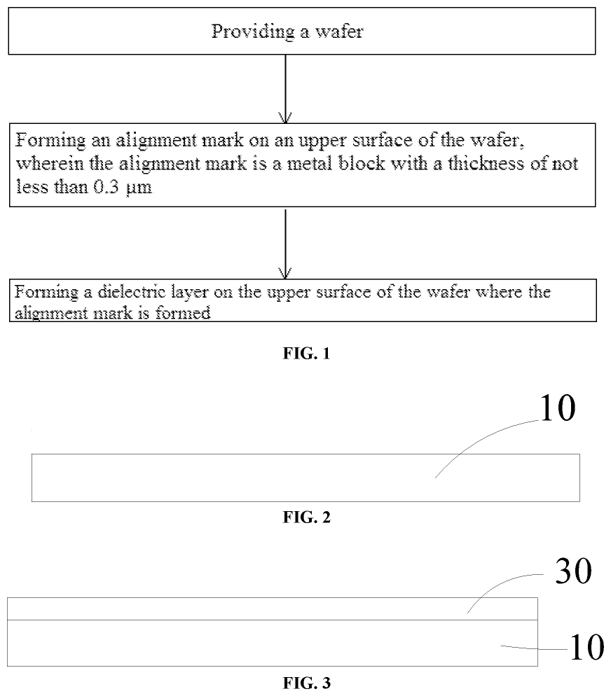

Referring to FIG. 1, the present application provides a method for preparing a dielectric layer on a surface of a wafer. In the method, an alignment mark 20 is formed on a wafer 10 by using a metal layer, so that the alignment mark 20 is relatively easily visible, and can be conveniently recognized in a subsequent technique and used for alignment. In a preferred embodiment of the present application, the method for preparing the dielectric layer on the surface of the wafer includes the following steps.

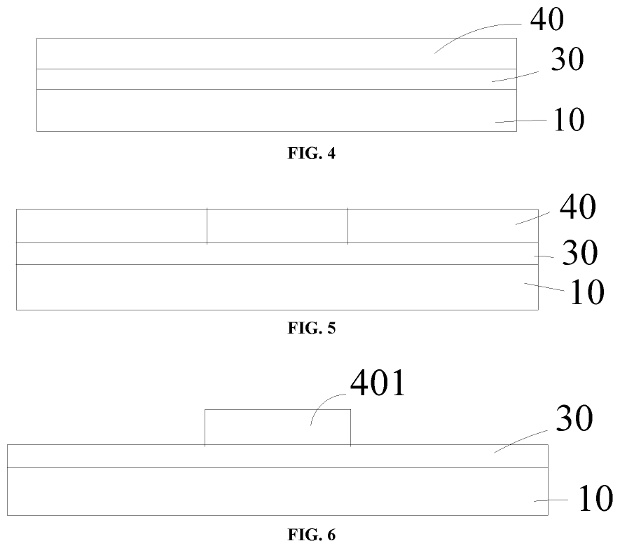

In S1, as shown in FIG. 2, a wafer 10 is provided, wherein the wafer 10 includes a substrate, a bonding pad 101 formed on the substrate and a passivation layer, and the bonding pad is exposed outwardly from a passivation layer opening in the passivation layer.

In S2, an alignment mark 20 is formed on an upper surface of the wafer 10, wherein the alignment mark 20 is a metal block with a thickness of not less than 0.3 μm, and is only arranged on the passivation layer of the wafer 10, and no alignment mark 20 is formed on the bonding pad 101 of the wafer 10.

In S3, a dielectric layer is formed on the upper surface of the wafer where the alignment mark 20 is formed.

The “forming an alignment mark 20 on an upper surface of the wafer 10” includes the following steps.

In S21, as shown in FIG. 3, the upper surface of the wafer 10 is covered with a metal layer 30, and the thickness of the metal layer 30 is not less than 0.3 μm.

In S22, the metal layer other than a target position is removed to form a metal block, wherein the target position is a position where the alignment mark is located.

Specifically, the metal layer 30 is an under-bump metallization (UBM) layer shaped on the upper surface of the wafer. The UBM layer is deposited on the surface of the wafer 10 by a magnetron sputtering technique, and is generally a composite layer of a multi-layer structure. In the present embodiment, the UBM layer includes a chromium layer, a chromium-copper layer and a copper layer from bottom to top. In another embodiment, the UBM layer may also be a nickel-containing metal composite layer. The metal layer 30 may be a metal such as Ti, Cu, Au and Al.

The metal layer 30 covers the whole surface of the wafer 10, and the UBM layer enables a magnification effect on a protrusion or dent on the surface of the wafer 10 during actual use. Covering the upper surface of the wafer 10 with the UBM layer can enable an original protrusion on the upper surface of the wafer 10 to be more obvious. In this way, for the wafer 10 with the above protrusion, a more obvious contrast mark 20 can be obtained, so that an alignment role of the alignment mark 20 can be better played in the subsequent technological process.

In the prior art, the alignment mark is prone to be smoothed by the dielectric layer after being covered with the dielectric layer, that is, it is difficult to find the position of the alignment mark on the dielectric layer. Thus, a chip cannot be aligned in an operation after the dielectric layer is formed. In the present embodiment, a protrusion of the metal layer 30 is formed on the upper surface of the wafer 10, and is used as a new alignment mark 20, so that the alignment mark 20 can be clearly displayed after the wafer 10 is covered with the dielectric layer. Of course, in other embodiments, the alignment mark 20 may also be a dent disposed on the surface of the wafer 10. It should be noted that the height of the alignment mark 20 when it is a protrusion cannot be less than 0.3 μm, and similarly, when it is a dent, the depth of the alignment mark 20 is not less than 0.3 μm.

Specifically, in S22, “removing the metal layer other than a target position to form a metal block” includes the following steps.

In S221, as shown in FIG. 4, the upper surface of the metal layer 30 is covered with a photoresist to form a photoresist layer 40, wherein the photoresist is a light-sensitive mixed liquid consisting of photosensitive resin, a photosensitive agent and a solvent, and after being illuminated, the photoresist will quickly experience a photo-curing reaction in an exposed region to obtain a required pattern or image.

In S222, as shown in FIGS. 5 and 6, the photoresist layer other than the target position is removed, so that the remaining photoresist layer forms a photoresist block 401 above the target position, wherein the metal layer 30 other than the target position is exposed outwardly, the target position is only located in an interval position above the passivation layer, and the target position does not include a region above the bonding pad. Specifically, the photoresist layer at the target position is shielded by using a mask, and the photoresist layer other than the target position is exposed; and then, the photoresist other than the target position is removed by means of a development technique, wherein the development technique is to dissolve the photoresist in a region other than the target position by using a chemical developer so as to enable the metal layer under the photoresist to be exposed on the surface of the wafer, and the target position is a position corresponding to the alignment mark 20.

In S223, as shown in FIGS. 6-8, the photoresist block is removed after the outwardly exposed metal layer other than the target position is removed to form the alignment mark 20. Specifically, an etching technique may be used to remove the metal layer other than the target position, so as to expose the wafer 10 below and keep the metal layer at the target position and the photoresist covering the surface of the metal layer. In this case, except the target position, the surface of the wafer 10 is not covered with the metal layer or the photoresist. Finally, the photoresist at the target position is removed, so that the metal layer is exposed on the surface of the wafer to form the alignment mark.

Specifically, the photoresist 30 at the target position can be removed by wet etching, so that the metal layer covered by the photoresist is exposed on the surface of the wafer 10. In this case, the surface of the wafer 10 is covered with the metal layer only at the target position, and the metal layer finally forms a metal bump, which protrudes from the surface of the wafer 10 and becomes the alignment mark on the surface of the wafer 10.

In “forming a dielectric layer on the surface of the wafer 10”, the dielectric layer may be a polyimide (PI) film.

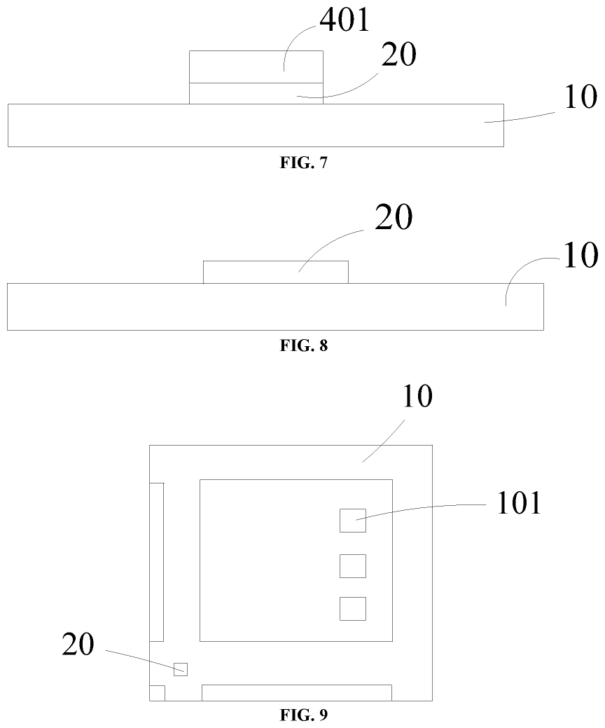

Another embodiment of the present invention further discloses a wafer structure. As shown in FIG. 9, the wafer structure includes a substrate, a bonding pad 101 formed on the substrate and a passivation layer, wherein the bonding pad is exposed outwardly from a passivation layer opening in the passivation layer; and
an alignment mark is formed on an upper surface of the passivation layer, and is a metal block with a thickness of not less than 0.3 μm, wherein the metal block is a UBM layer.

Another embodiment of the present invention further discloses a method for shaping a bump, including the following steps:
providing a wafer, wherein the wafer is provided with a substrate, a bonding pad formed on the substrate and a passivation layer, and the bonding pad is exposed outwardly from a passivation layer opening in the passivation layer;
forming an alignment mark on an upper surface of the wafer, wherein the alignment mark is a metal block with a thickness of not less than 0.3 μm;
forming a dielectric layer on the upper surface of the wafer where the alignment mark is formed;
removing the dielectric layer above the passivation layer opening to outwardly expose the bonding pad;
covering an upper surface of the dielectric layer and an upper surface of the bonding pad with a seed layer;
forming a photoresist layer on the seed layer, and removing the photoresist layer at a target position to form a photoresist layer pane for outwardly exposing the bonding pad; and
forming a metal bump in the photoresist layer pane.

In summary, the present application optimizes the processing technique of the wafer 10, in which the alignment mark is prepared in advance on the surface of the wafer 10 before the dielectric layer is shaped on the surface of the wafer 10. Since the thickness of the alignment mark is not less than 0.3 μm, the alignment mark is relatively prominent and easily visible after being covered with the dielectric layer, and can be effectively recognized for positioning in a subsequent technique of the wafer 10 (such as a preparation stage of the dielectric layer), which is beneficial to the proceeding of the subsequent technique, effectively avoids the problem of reworking due to the invisible alignment mark in the preparation stage of the dielectric layer, ensures the continuity of the process technique, improves the production efficiency and also saves the labor and material costs of the reworking.

The structure, features and effects of the present invention have been described in detail according to the embodiments shown in the drawings. The above are only preferred embodiments of the present invention, but the scope of implementations of the present invention is not limited by the drawings. Any changes made according to the concept of the present invention or equivalent embodiments modified to equivalent changes that do not go beyond the spirit covered by the Description and drawings should be within the scope of protection of the present invention.

What is claimed is:

1. A method for preparing a dielectric layer on a surface of a wafer, comprising:
providing a wafer, wherein the wafer is provided with a substrate, a bonding pad formed on the substrate and a passivation layer, and the bonding pad is exposed outwardly from a passivation layer opening in the passivation layer;
covering an upper surface of the wafer with a metal layer having a thickness of not less than 0.3 μm, wherein the metal layer is a UBM layer shaped on the upper surface of the wafer;
covering an upper surface of the metal layer with a photoresist to form a photoresist layer;
removing the photoresist layer other than a target position, such that the remaining photoresist layer forms a photoresist block above the target position, and the metal layer other than the target position is exposed outwardly;
removing the photoresist block after the outwardly exposed metal layer other than the target position is removed, so as to enable the metal layer at the target position to form a metal block which is used as an alignment mark on the upper surface of the wafer and is only arranged on the passivation layer; and
forming a dielectric layer on the upper surface of the wafer where the metal block is formed.

2. The method for preparing the dielectric layer on the surface of the wafer according to claim 1, wherein the UBM layer comprises a chromium layer, a chromium-copper layer and a copper layer from bottom to top.

3. The method for preparing the dielectric layer on the surface of the wafer according to claim 1, wherein “removing the photoresist layer other than a target position” comprises:
shielding a photoresist layer at the target position by using a mask, and exposing the photoresist layer other than the target position; and
removing the photoresist other than the target position by means of a development technique.

4. The method for preparing the dielectric layer on the surface of the wafer according to claim 3, wherein the development technique is to dissolve the photoresist in a region other than the target position by using a chemical developer, so as to enable the metal layer under the photoresist to be exposed on the surface of the wafer.

5. A wafer structure prepared by the method for preparing the dielectric layer on the surface of the wafer according to claim 1, comprising a substrate, a bonding pad formed on the substrate and a passivation layer, wherein the bonding pad is exposed outwardly from a passivation layer opening in the passivation layer; and
an alignment mark is formed on an upper surface of the passivation layer, and is a metal block with a thickness of not less than 0.3 μm.

6. The wafer structure according to claim 5, wherein the metal block is a UBM layer.

7. A method for shaping a bump, comprising:
providing a wafer, wherein the wafer is provided with a substrate, a bonding pad formed on the substrate and a passivation layer, and the bonding pad is exposed outwardly from a passivation layer opening in the passivation layer;
covering an upper surface of the wafer with a metal layer having a thickness of not less than 0.3 μm, wherein the metal layer is a UBM layer shaped on the upper surface of the wafer;
covering an upper surface of the metal layer with a photoresist to form a photoresist layer;
removing the photoresist layer other than a target position, such that the remaining photoresist layer forms a photoresist block above the target position and the metal layer other than the target position is exposed outwardly;
removing the photoresist block after the outwardly exposed metal layer other than the target position is removed, so as to enable the metal layer at the target position to form a metal block which is used as an alignment mark on the upper surface of the wafer and is only arranged on the passivation layer; forming a dielectric layer on the upper surface of the wafer where the alignment mark is formed;
removing the dielectric layer above the passivation layer opening to outwardly expose the bonding pad;
covering an upper surface of the dielectric layer and an upper surface of the bonding pad with a seed layer;
forming the photoresist layer on the seed layer, and then removing the photoresist layer at the target position to form a photoresist layer pane for outwardly exposing the bonding pad; and
shaping a metal bump in the photoresist layer pane.
